(19) United States
(12) Patent Application Publication
(10) Pub. No.: US 2022/0291548 A1
(43) Pub. Date: Sep. 15, 2022

(54) LIGHT FLUX CONTROLLING MEMBER, LIGHT EMITTING DEVICE, SURFACE LIGHT SOURCE DEVICE AND DISPLAY DEVICE

(71) Applicant: Enplas Corporation, Saitama (JP)

(72) Inventor: Yuki FUJII, Saitama (JP)

(73) Assignee: Enplas Corporation, Saitama (JP)

(21) Appl. No.: 17/690,027

(22) Filed: Mar. 9, 2022

(30) Foreign Application Priority Data
Mar. 12, 2021 (JP) 2021-040702

(51) Int. Cl. G02F 1/1335

(52) U.S. Cl. CPC G02F 1/133607

(57) ABSTRACT

A light flux controlling member includes a plurality of incidence units and a plurality of emission units. When light is entered into the light flux controlling member from a side surface of one emission unit of the plurality of emission units, an integrated value of an illuminance on a virtual line in a first region is greater than an integrated value of an illuminance on the virtual line in a second region on a virtual plane disposed immediately above the light flux controlling member and having a plan shape identical to that of the light flux controlling member, the virtual line passing through a first point located immediately above a center of gravity of the light flux controlling member and a second point located immediately above a center of the side surface on the virtual plane.

### RELATED APPLICATIONS

This application claims the benefit of priority of Japan Patent Application No. 2021-040702 filed on Mar. 12, 2021, the contents of which are incorporated herein by reference in their entirety.

### TECHNICAL FIELD

The present invention relates to a light flux controlling member, a light emitting device, a surface light source device and a display device.

### BACKGROUND ART

In recent years, in a transmission image display device such as a liquid crystal display apparatus, a direct surface light source device including a plurality of light emitting elements as the light source is used. In addition, in a direct surface light source device, a large number of light emitting elements are disposed in some cases in order to irradiate a wide range with light (see, for example, PTLS 1 and 2).

PTL 1 discloses an optical module including a plurality of light emitting elements disposed in a matrix, a light guide plate disposed over a plurality of light emitting elements, and a light shield scattering layer disposed over the light guide plate. The light guide plate includes a first main surface serving as a light emitting surface and a second main surface serving as an incidence surface. The first main surface includes a recess including an inclined surface and a flat part. In addition, the light shield scattering layer is disposed so as to cover the recess. The light emitted from the light emitting element impinges on the light guide plate at the second main surface, and is laterally reflected and emitted outward at the first main surface. The light emitted from the recess is scattered at the light shield scattering layer.

PTL 2 discloses a lighting module including a plurality of light sources disposed in a matrix, and a light guide plate disposed over a plurality of light emitting elements. The light emitted from the light source impinges on the light guide plate from the rear surface, and is emitted to the outside of the light guide plate while being guided at the front surface.

### CITATION LIST

### Patent Literature

PTL 1

Japanese Patent Application Laid-Open No. 2020-087889

PTL 2

Japanese Unexamined Patent Application Publication (Translation of PCT Application) No. 2009-506492

### SUMMARY OF INVENTION

### Technical Problem

In the surface light source device (optical module, lighting module) including the light guide plate described above, in some cases the light is desired to be emitted from a specific region in the light guide plate. In this case, it is conceivable to dispose the light guide plate after dividing the light guide plate into a plurality of pieces, and to emit light only from the light emitting element disposed in a specific region. In such a surface light source device, however, the light may propagate through a plurality of light guide plate pieces, in such a manner that the light emitted from the side surface of the first light guide plate piece impinges on the adjacent second light guide plate piece, and further the light emitted from the side surface of the second light guide plate piece impinges on the adjacent third light guide plate piece. If the light propagates through a plurality of light guide plate pieces, the luminance distribution in the surface light source device may become different from the desired distribution.

An object of the present invention is to provide a light flux controlling member that can suppress light propagation between light flux controlling members. In addition, another object of the present invention is to provide a light emitting device, a surface light source device and a display device including the light flux controlling member.

### Solution to Problem

A light flux controlling member according to an embodiment of the present invention is configured to control a distribution of light emitted from a plurality of light emitting elements disposed on a substrate, the light flux controlling member including: a plurality of incidence units configured to allow incidence of the light emitted from the plurality of light emitting elements; and a plurality of emission units disposed between the plurality of incidence units in a direction along the substrate, and configured to emit light entered from the plurality of incidence units while guiding the light entered from the plurality of incidence units. Each of the plurality of incidence units includes: an incidence surface disposed on a rear side of the light flux controlling member, and configured to allow incidence of light emitted from each of the plurality of light emitting elements, and a first reflection surface disposed on a front side of the light flux controlling member, and configured to laterally reflect light entered from the incidence surface, in a direction away from an optical axis of each of the plurality of light emitting elements. Each of the plurality of emission units includes: an emission promotion part disposed on the rear side of the light flux controlling member, and configured to promote emission of light being guided inside each of the plurality of emission units, and an emission part disposed on a front side of the light flux controlling member, and configured to emit light that has been guided inside each of the plurality of emission units. When light is entered into the light flux controlling member from a side surface of one emission unit of the plurality of emission units, an integrated value of an illuminance on a virtual line in a first region is greater than an integrated value of an illuminance on the virtual line in a second region on a virtual plane disposed immediately above the light flux controlling member and having a plan shape identical to that of the light flux controlling member, the virtual line passing through a first point located immediately above a center of gravity of the light flux controlling member and a second point located immediately above a center of the side surface on the virtual plane, the first region being located on a second point side with respect to the first point, the second region being located on a side opposite to the second point with respect to the first point.

A light emitting device according to an embodiment of the present invention includes: a plurality of light emitting elements; and the light flux controlling member.

A surface light source device according to an embodiment of the present invention includes: a substrate; a plurality of the light emitting devices disposed on the substrate and separated from each other; and a light diffusion plate disposed over the plurality of light emitting devices.

A display device according to an embodiment of the present invention includes: the surface light source device; and a display member configured to be irradiated with light emitted from the surface light source device.

### Advantageous Effects of Invention

According to the present invention, it is possible to provide a light flux controlling member that suppresses light propagation between light flux controlling members. In addition, according to the present invention, it is possible to provide a light emitting device, a surface light source device and a display device including the light flux controlling member.

### BRIEF DESCRIPTION OF DRAWINGS

FIG. 1A is a plan view of a surface light source device according to an embodiment of the present invention, and FIG. 1B is a front view of the surface light source device according to the embodiment of the present invention;

FIG. 2A is a sectional view taken along line A-A of FIG. 1B, and FIG. 2B is a sectional view taken along line B-B of FIG. 1A;

FIG. 3 is a partially enlarged sectional view of FIG. 2B;

FIG. 4 is a perspective view of the light flux controlling member according to the embodiment of the present invention;

FIG. 5A is a plan view of the light flux controlling member according to the embodiment of the present invention, and FIG. 5B is a bottom view of the light flux controlling member according to the embodiment of the present invention;

FIG. 6A is a front view of the light flux controlling member according to the embodiment of the present invention, FIG. 6B is a sectional view taken along line A-A of FIG. 5A, FIG. 6C is a plan view of an emission promotion part, and FIG. 6D is a plan view of another emission promotion part;

FIG. 7 is a diagram illustrating light paths of a light emitting device;

FIG. 8 is a schematic view illustrating light propagation in the surface light source device;

FIG. 9A is a schematic view of the light flux controlling member and a light source, and FIG. 9B is a graph schematically illustrating an illuminance distribution;

FIG. 10A is a plan view of an apparatus for measuring the illuminance distribution,

FIG. 10B is a front view of the apparatus for measuring the illuminance distribution, and FIG. 10C is a right side view of the apparatus for measuring the illuminance distribution;

FIG. 11A is an illuminance distribution obtained by using a light flux controlling member including an emission promotion part that exhibits Lambertian scattering, FIG. 11B is an illuminance distribution obtained by using a light flux controlling member including an emission promotion part that exhibits Cos5 power scattering, FIG. 11C is an illuminance distribution obtained by using a light flux controlling member including an emission promotion part that exhibits Cos10 power scattering, FIG. 11D is an illuminance distribution obtained by using a light flux controlling member including an emission promotion part that exhibits Cos50 power scattering, FIG. 11E is an illuminance distribution obtained by using a light flux controlling member including an emission promotion part that exhibits Cos100 power scattering, and FIG. 11F is an illuminance distribution obtained by using a light flux controlling member including an emission promotion part that exhibits Cos500 power scattering;

FIG. 12A is a graph illustrating an illuminance distribution on line A illustrated in FIGS. 11A to 11F, and FIG. 12B is a graph illustrating an illuminance distribution on line B illustrated in FIGS. 11A to 11F;

FIG. 13A is an illuminance distribution obtained by using a light flux controlling member provided with no emission promotion part, and FIG. 13B is an illuminance distribution obtained by using the light flux controlling member including the emission promotion part of the embodiment of the present invention;

FIG. 14A is a graph illustrating an illuminance distribution on line A illustrated in FIGS. 13A and 13B, and FIG. 14B is a graph illustrating an illuminance distribution on line B illustrated in FIGS. 13A and 13B;

FIG. 15 is a graph illustrating an illuminance distribution on line C illustrated in FIGS. 13A and 13B;

FIG. 16A is an illuminance distribution in a surface light source device according to a comparative example, FIG. 16B is an illuminance distribution in the surface light source device according to an embodiment of the present invention; and

FIG. 17A is a graph illustrating an illuminance distribution on the line A illustrated in FIGS. 16A and 16B, and FIG. 17B is a graph illustrating an illuminance distribution on the line B illustrated in FIGS. 16A and 16B.

### DESCRIPTION OF EMBODIMENTS

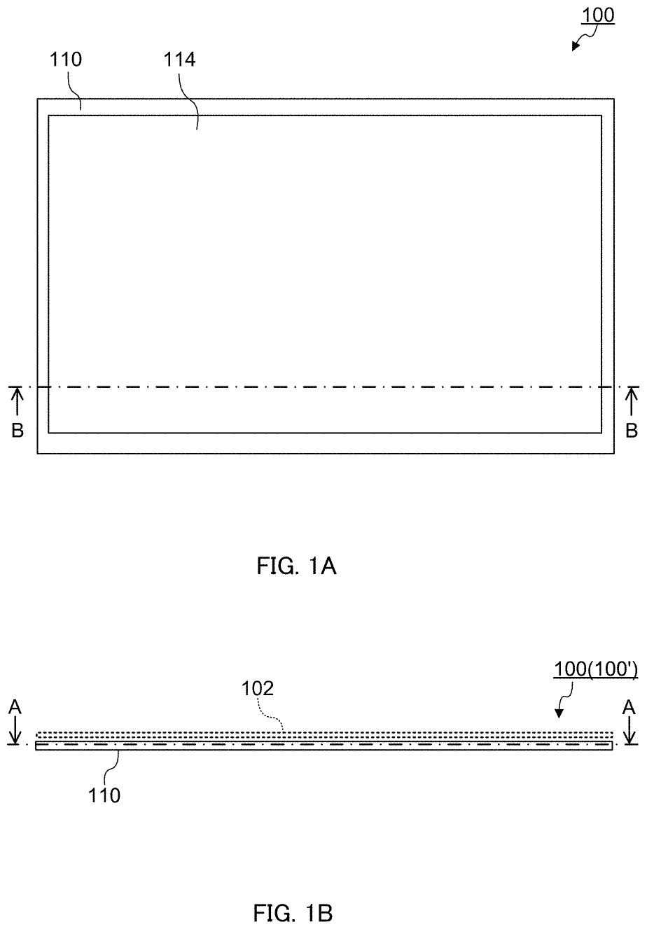

An embodiment of the present invention will be described below with reference to the accompanying drawings. In the following description, as a typical example of a surface light source device according to an embodiment of the present invention, a surface light source device suitable for a backlight of a liquid crystal display apparatus and the like is described. This surface light source device can be used as display device 100′ when combined with display member 102 (e.g., a liquid crystal panel) to be irradiated with light from a surface light source device (see FIG. 1B).

### Configurations of Surface Light Source Device and Light Emitting Device

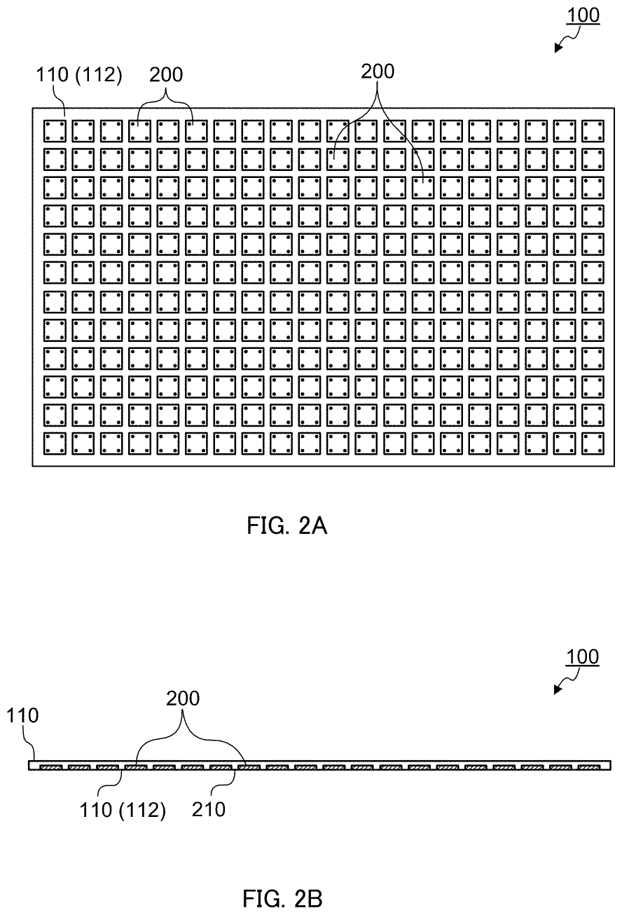

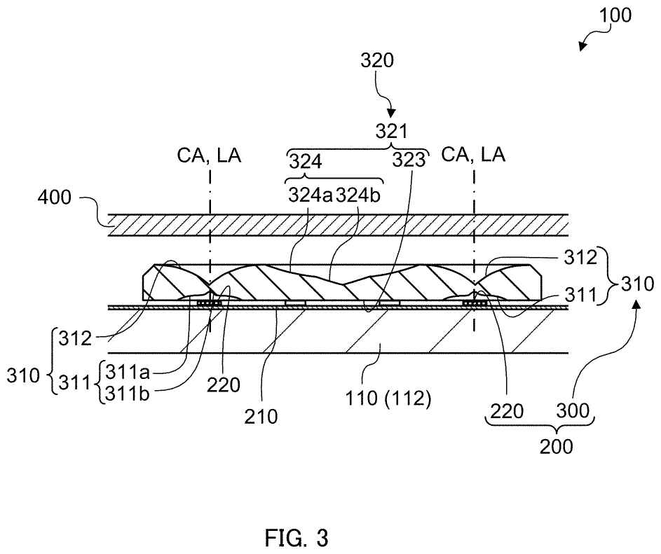

FIG. 1A is a plan view of surface light source device 100 according to the embodiment of the present invention. FIG. 1B is a front view of surface light source device 100 according to the embodiment of the present invention. FIG. 2A is a sectional view taken along line A-A of FIG. 1B. FIG. 2B is a sectional view taken along line B-B of FIG. 1A. FIG. 3 is a partially enlarged sectional view of FIG. 2B.

As illustrated in FIGS. 1A to 3, surface light source device 100 according to the present embodiment includes housing 110, a plurality of light emitting devices 200 and light diffusion plate 400. The plurality of light emitting devices 200 is disposed in a grid (matrix) pattern on bottom plate 112 of housing 110. A reflection sheet may be disposed on the surface of bottom plate 112 or substrate 210 such that the surface of the reflection sheet functions as a diffusive reflection surface, or the surface of bottom plate 112 or substrate 210 may function as a diffusive reflection surface. In the present embodiment, the surface of substrate 210 functions as a diffusive reflection surface. In addition, an opening is provided in top plate 114 of housing 110. Light diffusion plate 400 is disposed to close the opening, and functions as a light emitting surface. The size of light emitting surface is not limited, but may be approximately 400 mm×approximately 700 mm, for example.

As illustrated in FIG. 3, light emitting device 200 is fixed on substrate 210. Substrate 210 is fixed at a predetermined position on bottom plate 112 of housing 110. Light emitting device 200 includes a plurality of light emitting elements 220 and light flux controlling member 300. In light emitting device 200, the plurality of light emitting elements 220 is disposed in a grid pattern.

Light emitting element 220 is a light source of surface light source device 100, and is mounted on substrate 210. The type of light emitting element 220 is not limited, but is light emitting element 220 that emits light from the top surface and the side surface (e.g., a COB type light emitting diode) in the present embodiment. The size of one side of light emitting element 220 is not limited, but is within a range of 0.1 to 0.6 mm, for example. For example, the size of light emitting element 220 is 0.2 mm×0.38 mm. In addition, preferably, the distance between substrate 210 and light diffusion plate 400 is 5 mm or smaller. Note that in the present embodiment, the distance between substrate 210 and light diffusion plate 400 is 3 mm.

Light flux controlling member 300 is an optical member that controls the distribution of light emitted from the plurality of light emitting elements 220. Light flux controlling member 300 is fixed on substrate 210. Light flux controlling member 300 is formed by integral shaping. The material of light flux controlling member 300 is resin or glass that can transmit light of a desired wavelength. Examples of the resin include polymethylmethacrylate (PMMA), polycarbonate (PC), and epoxy resin (EP).

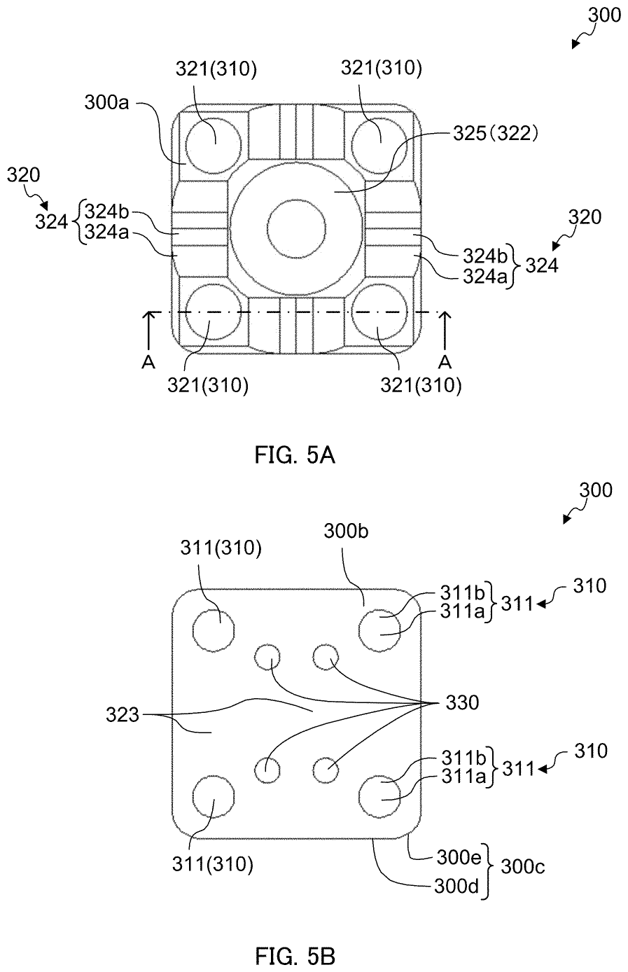

In the present embodiment, light flux controlling member 300 is disposed over the plurality of light emitting elements 220 such that central axis CA of each incidence unit 310 (incidence surface 311) coincides with light axis LA of each light emitting element 220. Note that in light flux controlling member 300 according to the present embodiment, the shape of incidence unit 310 (incidence surface 311 and first reflection surface 312) is rotationally symmetrical (circularly symmetrical). The rotation axis of incidence unit 310 is referred to as “central axis CA of incidence unit 310, incidence surface 311 or first reflection surface 312”. In addition, “light axis LA of light emitting element 220” means a central light beam of a stereoscopic emission light flux from light emitting element 220. A gap for dissipating the heat from light emitting element 220 to the outside may or may not be formed between substrate 210 where light emitting element 220 is mounted and rear side surface 300b (see FIG. 5B) of light flux controlling member 300. In the present embodiment, a gap is formed between substrate 210 where light emitting element 220 is mounted and rear side surface 300b of light flux controlling member 300, with leg part 330 described later. A configuration of light flux controlling member 300 according to the present embodiment will be separately elaborated later.

Light diffusion plate 400, which is a plate-shaped member with light diffusibility, transmits light emitted from light emitting device 200 while diffusing the light. Normally, light diffusion plate 400 has substantially the same size as a display member such as a liquid crystal panel. Examples of the material of light diffusion plate 400 include optically transparent resins such as polymethylmethacrylate (PMMA), polycarbonate (PC), polystyrene (PS), and styrene methyl methacrylate copolymerization resin (MS). To provide light diffusion plate 400 with the light diffusibility, minute irregularities are formed in the surface of light diffusion plate 400, or a light diffuser such as beads are dispersed inside light diffusion plate 400.

In surface light source device 100 according to the present embodiment, the light emitted from each light emitting element 220 is controlled by light flux controlling member 300 to illuminate only a specific region of light diffusion plate 400. The light emitted from each light flux controlling member 300 is diffused by light diffusion plate 400. As a result, surface light source device 100 according to the present embodiment can illuminate a planar display member (e.g., a liquid crystal panel) with a desired illuminance distribution.

In the present embodiment, preferably, the plurality of light emitting devices 200 is disposed in a grid pattern and separated from each other. The distance between light emitting devices 200 adjacent to each other may be smaller than half the center-to-center distance of the plurality of light emitting elements 220. Here, “the center-to-center distance of the plurality of light emitting elements 220” means the center-to-center distance of two light emitting elements 220 adjacent to each other that belong to respective light emitting devices 200 different from each other. The center-to-center distance of light emitting elements 220 adjacent to each other in the direction along the side of light flux controlling member 300 may be identical to or different from the center-to-center distance of light emitting elements 220 adjacent to each other in different light emitting devices 200. In the present embodiment, the distance between light emitting devices 200 adjacent to each other is 6 mm.

### Configuration of Light Flux Controlling Member

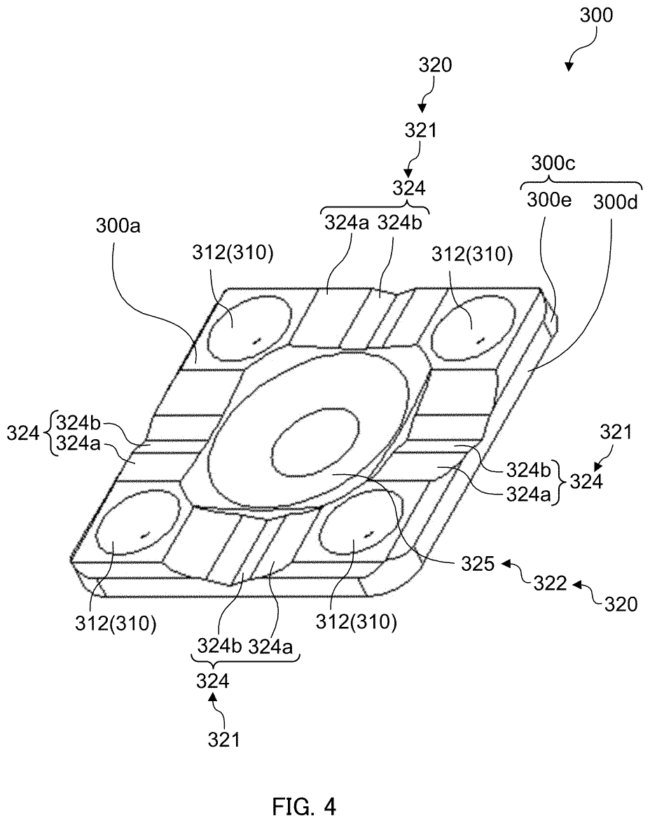

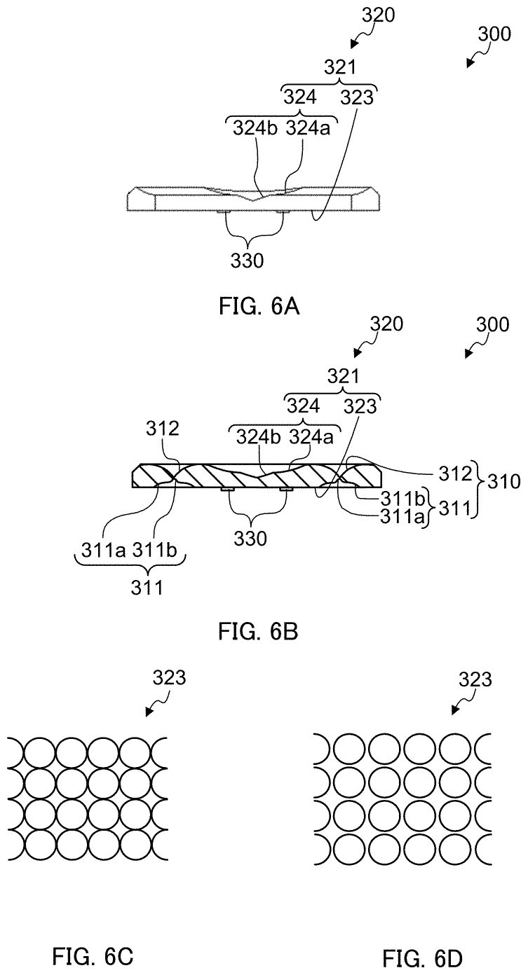

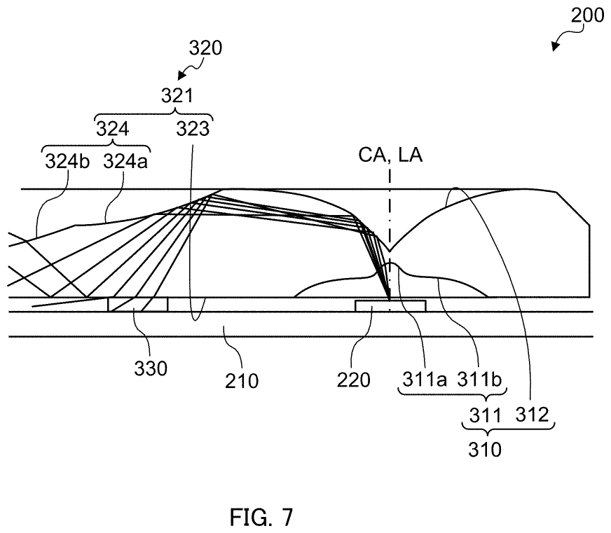

FIG. 4 is a perspective view of light flux controlling member 300 according to the embodiment of the present invention. FIG. 5A is a plan view of light flux controlling member 300 according to the embodiment of the present invention. FIG. 5B is a bottom view of light flux controlling member 300 according to the embodiment of the present invention. FIG. 6A is a front view of light flux controlling member 300 according to the embodiment of the present invention. FIG. 6B is a sectional view taken along line A-A of FIG. 5A. FIG. 6C is a plan view of emission promotion part 323. FIG. 6D is a plan view of another emission promotion part 323. FIG. 7 is a diagram illustrating light paths of light emitting device 200.

Light flux controlling member 300 is an optical member for controlling the orientation of the light emitted from the plurality of light emitting elements 220 disposed on substrate 210. Light flux controlling member 300 according to the present embodiment includes a plurality of incidence units 310 and a plurality of emission units 320. Note that light flux controlling member 300 according to the present embodiment further includes leg part 330.

The plurality of incidence units 310 is disposed in a grid pattern corresponding to the arrangement of light emitting elements 220. Emission unit 320 is disposed between the plurality of incidence units 310 in the direction along substrate 210. The shape of light flux controlling member 300 in plan view is not limited. In the present embodiment, the shape of light flux controlling member 300 in plan view is a substantially square shape with chamfered corners. In the present embodiment, the length of one side of the substantially square shape is 18 mm. Incidence units 310 are disposed in the vicinity of respective corners of the substantially square shape. In addition, first emission unit 321 is disposed in the vicinity of the side of the substantially square shape, and second emission unit 322 is disposed at the center portion of the substantially square shape.

The external shape of light flux controlling member 300 is formed with front side surface 300a, rear side surface 300b, and side surface 300c. Front side surface 300a includes first reflection surface 312 of incidence unit 310, first emission part 324 of first emission unit 321, and second emission part 325 of second emission unit 322. Rear side surface 300b includes incidence surface 311 of incidence unit 310, and emission promotion part 323 of first emission unit 321 and second emission unit 322. Side surface 300c includes first side surface 300d that is a side surface of first emission unit 321 and second side surface 300e that is a side surface of incidence unit 310 in plan view of light flux controlling member 300. The shape of first side surface 300d is not limited, and may be a flat surface or a curved surface, or, may have a plurality of recesses or a plurality of protrusions. The shape of second side surface 300e is not limited. The shape of second side surface 300e may be a curved surface, or a plurality of flat surfaces. In the present embodiment, second side surface 300e is a curved surface.

The plurality of incidence units 310 allows incidence of light emitted from light emitting element 220. Incidence unit 310 includes incidence surface 311 disposed on the rear side of surface 300b to allow incidence of light emitted from light emitting element 220, first reflection surface 312 disposed on the front side of surface 300a to reflect, toward emission unit 320, light entered from incidence surface 311, and second side surface 300e.

Incidence surface 311 is an inner surface of a recess disposed on the rear side of surface 300b light flux controlling member 300 at a position facing light emitting element 220. Incidence surface 311 allows a large part of the light emitted from light emitting element 220 to enter light flux controlling member 300 while controlling the travelling direction of the light. Incidence surface 311 intersects light axis LA of light emitting element 220, and is rotationally symmetrical (circularly symmetrical) about light axis LA. The shape of incidence surface 311 is not limited, and is set such that the light entered from incidence surface 311 travels toward first reflection surface 312 and emission surface 324b.

In the present embodiment, incidence surface 311 includes first incidence surface 311a and second incidence surface 311b.

First incidence surface 311a is disposed to intersect light axis LA of light emitting element 220. First incidence surface 311a is formed such that it goes toward the rear side as it goes away from central axis CA increases. In addition, in the cross section including central axis CA, first incidence surface 311a has a shape in which the gradient of its tangent gradually decreases as the distance from central axis CA increases.

Second incidence surface 311b is disposed outside first incidence surface 311a. Second incidence surface 311b is formed such that it goes toward the rear side as it goes away from central axis CA. In addition, in the cross section including central axis CA, second incidence surface 311b has a shape in which the gradient of its tangent gradually decreases as the distance from central axis CA increases. First incidence surface 311a and second incidence surface 311b are smoothly connected with each other.

First reflection surface 312 is disposed on the front side of light flux controlling member 300 at a position opposite to light emitting element 220 with incidence surface 311 therebetween, and laterally reflects light entered from incidence surface 311 in the direction away from light axis LA of light emitting element 220. The term “laterally” does not mean the direction of the outer edge of light flux controlling member 300, but means that it goes outward in the radial direction 360° around the optical axis.

In this manner, first reflection surface 312 prevents the generation of bright spots at a position immediately above light emitting element 220 by reducing the upward transmission of the light entered from incidence surface 311, and prevents the generation of dark points at the region between light emitting elements 220 by guiding the light to the region between light emitting element 220. The shape of first reflection surface 312 is not limited as long as the light entered from incidence surface 311 can be laterally reflected. In the present embodiment, first reflection surface 312 is configured to be rotationally symmetrical (circularly symmetrical) about central axis CA, and configured such that it goes toward the front side (goes away from substrate 210) as it goes away from central axis CA.

The generatrix from the center to the outer periphery of the rotationally symmetrical shape is a curved or straight line that is tilted with respect to the optical axis of light emitting element 220. First reflection surface 312 is a recessed surface obtained by rotating 360° the generatrix around central axis CA of incidence surface 311 as the rotation axis. In the present embodiment, the generatrix is a curve.

Emission unit 320 emits the light entered from the plurality of incidence units 310 while guiding the light. As described above, in the present embodiment, emission unit 320 includes first emission unit 321 disposed at the outer periphery of light flux controlling member 300, and second emission unit 322 disposed at the center of light flux controlling member 300.

The configuration of first emission unit 321 is not limited as long as the above-mentioned function can be ensured. In the present embodiment, first emission unit 321 includes emission promotion part 323, first emission part 324, and a part of first side surface 300d.

Emission promotion part 323 is disposed on rear side surface 300b, and promotes outward emission of the light advanced inside light flux controlling member 300, from first emission part 324 (and side surface 300c) to the outside of light flux controlling member 300. The configuration of emission promotion part 323 is not limited as long as the above-mentioned function can be ensured. Examples of the configuration of emission promotion part 323 include one large protrusion formed to protrude from rear side surface 300b, and one large recess formed to depress from rear side surface 300b. In addition, examples of the configuration of emission promotion part 323 include a plurality of small protrusions and a plurality of small recesses. A plurality of protrusions and a plurality of recesses may be in contact with each other, or separated from each other. As illustrated in FIG. 6C, in the present embodiment, emission promotion part 323 is a plurality of (hemispherical) protrusions. In the present embodiment, the protrusion has a hemispherical shape. The radius of the hemispherical shape is not limited. Preferably, the radius is 1 mm or smaller. In the present embodiment, the radius is 0.1 mm. In addition, in the case where an elliptical spherical shape is used as the protrusion, it is preferable that the radius be 2 mm or smaller. Emission promotion part 323 may be disposed in a part of rear side surface 300b, or in the entire surface of rear side surface 300b except for incidence surface 311. Emission promotion part 323 may be disposed in the entire surface of rear side surface 300b except for incidence surface 311 (see FIG. 6C), or in substantially the entire surface of rear side surface 300b except for incidence surface 311 (see FIG. 6D). In the present embodiment, emission promotion part 323 is disposed in the entire surface of rear side surface 300b except for incidence surface 311. How emission promotion part 323 distributes the arriving light will be described later.

First emission part 324, which is disposed in front side surface 300a, internally reflects, toward rear side surface 300b, the light internally reflected by first reflection surface 312, and emits the advanced light to the outside of light flux controlling member 300. The configuration of first emission part 324 is not limited as long as the above-mentioned function can be ensured. In the present embodiment, first emission part 324 includes second reflection surface 324a and emission surface 324b.

Second reflection surface 324a internally reflects, toward emission promotion part 323, the light reflected by first reflection surface 312 (see FIG. 7). The shape of second reflection surface 324a is not limited as long as the above-mentioned function can be ensured. Second reflection surface 324a may be a flat surface or a curved surface. In the present embodiment, second reflection surface 324a is a curved surface. More specifically, second reflection surface 324a has a curvature in the direction along the side of light flux controlling member 300 closest to second reflection surface 324a, but does not have a curvature in the direction orthogonal to the direction along the side of light flux controlling member 300 closest to second reflection surface 324a. In addition, in the present embodiment, in the direction along the side of light flux controlling member 300, second reflection surface 324a is disposed on the outside (at both end portions) of first emission part 324.

Emission surface 324b emits the light that has advanced inside first emission unit 321, to the outside of light flux controlling member 300 (see FIG. 7). The shape of emission surface 324b is not limited as long as the above-mentioned function can be ensured. The shape of emission surface 324b may be a flat surface or a curved surface. In the present embodiment, the shape of emission surface 324b is a combination of a plurality of flat surfaces. In addition, in the present embodiment, emission surface 324b is disposed on the inside (at center portion) of first emission part 324 in the direction along of the side of light flux controlling member 300. It is preferable that emission surface 324b be a recessed surface whose vertex is the center of optical control member 300 as in the present embodiment.

First side surface 300d connects second reflection surface 324a and emission surface 324b, and emission promotion part 323. First side surface 300d emits the light that has been guided inside light flux controlling member 300, and allows incidence of the light emitted from light emitting devices 200 adjacent to each other.

The configuration of second emission unit 322 is not limited as long as the above-mentioned function can be ensured. In the present embodiment, second emission unit 322 includes emission promotion part 323 and second emission part 325. Emission promotion part 323 is the same as emission promotion part 323 of first emission part 324, and therefore the description thereof will be omitted.

Second emission part 325 reflects a part of the light from incidence unit 310, and emits the other part. The shape of second emission part 325 is not limited as long as the above-mentioned function can be ensured. In the present embodiment, second emission part 325 is a recessed surface composed of the upper bottom and the side surface of a truncated conical shape disposed upside down. The upper bottom of the truncated conical shape functions as an emission surface, and the side surface functions as a reflection surface.

### Propagation of Light

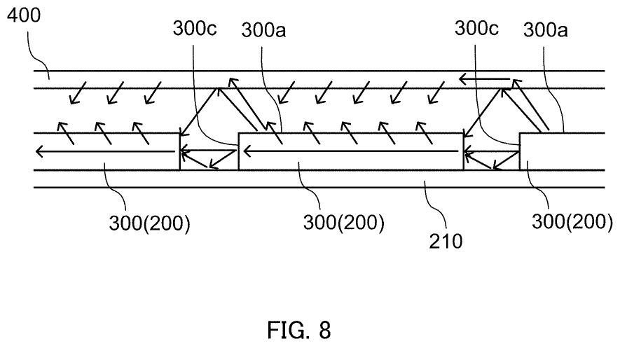

Here, in surface light source device 100 of the embodiment of the present invention, in some cases it is desired to emit light from only a predetermined region of light emitting surface (light diffusion plate 400). In this case, it is important that how the light emitted from light emitting element 220 advances and reaches light diffusion plate 400. In view of this, propagation of light emitted from light emitting element 220 is described below. Here, it is assumed that light flux controlling member 300 is not provided with emission promotion part 323. FIG. 8 is a schematic view illustrating light propagation in the surface light source device.

In a certain light emitting device 200 (hereinafter also referred to as “first light emitting device 200”; light emitting device 200 on the right side in FIG. 8), the light distribution of light emitted from light emitting element 220 is controlled at light flux controlling member 300.

As illustrated in FIG. 8, light emitted from front side surface 300a (e.g., emission surface 324b) of light flux controlling member 300 of first light emitting device 200 reaches a region immediately above first light emitting device 200 in light diffusion plate 400. A large part of the light having reached light diffusion plate 400 transmits through light diffusion plate 400, while a part of the light having reached light diffusion plate 400 is reflected by light diffusion plate 400. A part of the light reflected by light diffusion plate 400 reaches and enters light flux controlling member 300 of adjacent light emitting devices 200 (hereinafter referred to also as “second light emitting device 200”; light emitting device 200 at the center in FIG. 8). The light having entered light flux controlling member 300 of second light emitting device 200 is gradually emitted toward light diffusion plate 400 while being guided inside the light flux controlling member 300, and reaches the region immediately above second light emitting device 200 in light diffusion plate 400.

In addition, a part of the light emitted from side surface 300c (e.g., first side surface 300d) of light flux controlling member 300 of first light emitting device 200 reaches and enters light flux controlling member 300 of adjacent second light emitting device 200. The light having entered light flux controlling member 300 of second light emitting device 200 is gradually emitted toward light diffusion plate 400 while being guided inside the light flux controlling member 300. In addition, a part of the light is emitted from side surface 300c of light flux controlling member 300 of second light emitting device 200.

Further, a part of the light emitted from front surface 300a (e.g., emission surface 324b) of light flux controlling member 300 of second light emitting device 200 is reflected by light diffusion plate 400 again, and reaches and enters light flux controlling member 300 of adjacent light emitting devices 200 (hereinafter referred to also as “third light emitting device 200”; left light emitting device 200 in FIG. 8). In addition, a part of the light emitted from side surface 300c (e.g., first side surface 300d) of light flux controlling member 300 of second light emitting device 200 reaches and enters light flux controlling member 300 of adjacent third light emitting device 200. The light having entered light flux controlling member 300 of third light emitting device 200 is gradually emitted toward light diffusion plate 400 while being guided inside the light flux controlling member 300. In addition, a part of the light is emitted from side surface 300c of light flux controlling member 300 of third light emitting device 200.

As described above, in the case where there is a space between each light emitting device 200, the light emitted from light emitting element 220 of first light emitting device 200 may reach not only a region immediately above first light emitting device 200 in light diffusion plate 400, but also a region immediately above another light emitting device 200 in light diffusion plate 400 through light flux controlling member 300 of second light emitting device 200 and/or third light emitting device 200 even when light is not emitted from light emitting element 220 of other light emitting devices 200 such as second light emitting device 200 and third light emitting device 200. If the light emitted from light flux controlling member 300 of first light emitting device 200 propagates to light flux controlling member 300 of other light emitting device 200 in the above-mentioned manner, the illuminance distribution at the light emitting surface (light diffusion plate 400) becomes largely different from the desired distribution.

In view of this, in the present invention, emission promotion part 323 is provided to light flux controlling member 300 for the purpose of reducing a situation where the light emitted from light flux controlling member 300 of first light emitting device 200 and having entered light flux controlling member 300 of second light emitting device 200 adjacent to first light emitting device 200 enters light flux controlling member 300 of third light emitting device 200 adjacent to second light emitting device 200.

For example, in the case where light flux controlling member 300 of second light emitting device 200 includes emission promotion part 323, the light emitted from side surface 300c (e.g., first side surface 300d) of light flux controlling member 300 of first light emitting device 200 and having entered light flux controlling member 300 of second light emitting device 200 is actively emitted from front surface 300a (e.g., emission surface 324b) of light flux controlling member 300 of second light emitting device 200 due to the effect of emission promotion part 323. Thus, in front surface 300a of light flux controlling member 300 of second light emitting device 200, the emission level in the region on the first light emitting device 200 side is significantly larger than the emission level in the region on third light emitting device 200 side. Accordingly, the light emitted from light flux controlling member 300 of second light emitting device 200 toward light flux controlling member 300 of third light emitting device 200 is reduced. As a result, it is possible to reduce the sequential light propagation from light flux controlling member 300 of first light emitting device 200, to light flux controlling member 300 of second light emitting device 200 and light flux controlling member 300 of third light emitting device 200.

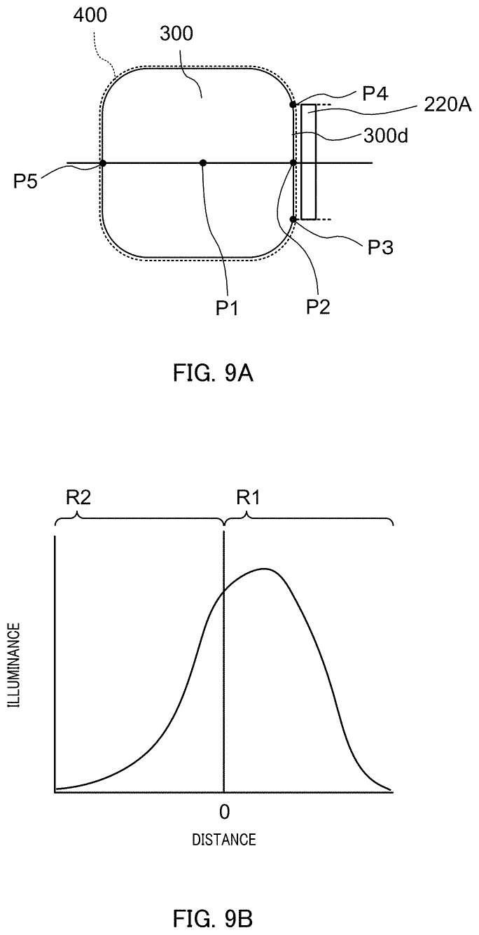

The effect of emission promotion part 323, i.e., the degree of light guidance inside light flux controlling member 300 can be determined by the following method. FIG. 9A is a schematic view of light flux controlling member 300 and light source 220A. FIG. 9B is a graph schematically illustrating an illuminance distribution.

As illustrated in FIG. 9A, first, light source 220A of Lambertian light distribution is disposed on the side of light flux controlling member 300, and light is entered from only the entire surface of one first side surface 300d of light flux controlling member 300. Note that light source 220A is appropriately selected in accordance with the shape of first side surface 300d. More specifically, light source 220A with a light emitting surface having a shape complementary to the shape of first side surface 300d is used. Note that in this experiment, first side surface 300d is a flat surface, and therefore the light emitting surface of light source 220A is also a flat surface. When the points closest to side surface 300c (first side surface 300d) from the centers of first reflection surfaces 312 of two incidence units 310 most distant from each other in the plurality of incidence units 310 disposed along side surface 300c (first side surface 300d) are set as third point P3 and fourth point P4, light source 220A is a planar light source that allows incidence of light at least from side surface 300c (first side surface 300d) between third point P3 and fourth point P4. Then, the illuminance at a virtual plane (light diffusion plate 400) disposed immediately above light flux controlling member 300 and having a shape identical to the plan shape of light flux controlling member 300 is measured. More specifically, the illuminance on the virtual plane corresponding to a virtual line, which passes through first point P1 immediately above the center of gravity of light flux controlling member 300, second point P2 immediately above the center of first side surface 300d opposite to light source 220A, and fifth point P5 immediately above the center of first side surface 300d on the side opposite to second point

P2, is measured on the virtual plane.

As illustrated in FIG. 9B, next, a relationship between the distance from first point (the center of gravity of the virtual plane) P1 (e.g., X-axis direction) and the measured illuminance (e.g., Y-axis direction) is illustrated in a graph. Next, with respect to first point P1 as a boundary, the graph is separated into first region R1 close to second point (first side surface 300d or light source 220A) P2, and second region (fifth point P5 close to region) R2 remote from second point P2. Next, the integrated value of the illuminance of first region R1 is determined by integrating the illuminance in first region R1. Likewise, the integrated value of the illuminance of second region R2 is determined by integrating the illuminance in second region R2.

When the integrated value of the illuminance of first region R1 is greater than the integrated value of the illuminance of second region R2 as a result of comparison between the integrated value of the illuminance of first region R1 and the integrated value of the illuminance of second region R2, it is determined that emission promotion part 323 is effectively functioning and that the sequential light propagation from light flux controlling member 300 to another light flux controlling member 300 can be suppressed. Conversely, when the integrated value of the illuminance of first region R1 is smaller than the integrated value of the illuminance of second region R2, it is determined that the sequential light propagation from light flux controlling member 300 to another light flux controlling member 300 cannot be sufficiently suppressed. In light flux controlling member 300 according to the embodiment of the present invention, emission promotion part 323 effectively functions, and therefore the integrated value of the illuminance of first region R1 is greater than the integrated value of the illuminance of second region R2.

Next, the condition of emission promotion part 323 for the integrated value of the illuminance to meet the above-mentioned relationship was examined. Here, the determination was made based on the reflection of light entered from first side surface 300d of light flux controlling member 300 and reached emission promotion part 323. In this experiment, the illuminance on a virtual plane were examined by using a light flux controlling member including an emission promotion part that exhibits Lambertian scattering with the largest scattering of reflection light, and light flux controlling members with less scattering degrees, namely, a light flux controlling member including an emission promotion part that exhibits Cos5 power scattering of reflection light in a simulation, a light flux controlling member including an emission promotion part that exhibits Cos10 power scattering of reflection light in a simulation, a light flux controlling member including an emission promotion part that exhibits Cos50 power scattering of reflection light in a simulation, a light flux controlling member including an emission promotion part that exhibits Cos100 power scattering of reflection light in a simulation, and a light flux controlling member including an emission promotion part that exhibits Cos500 power scattering of reflection light in a simulation.

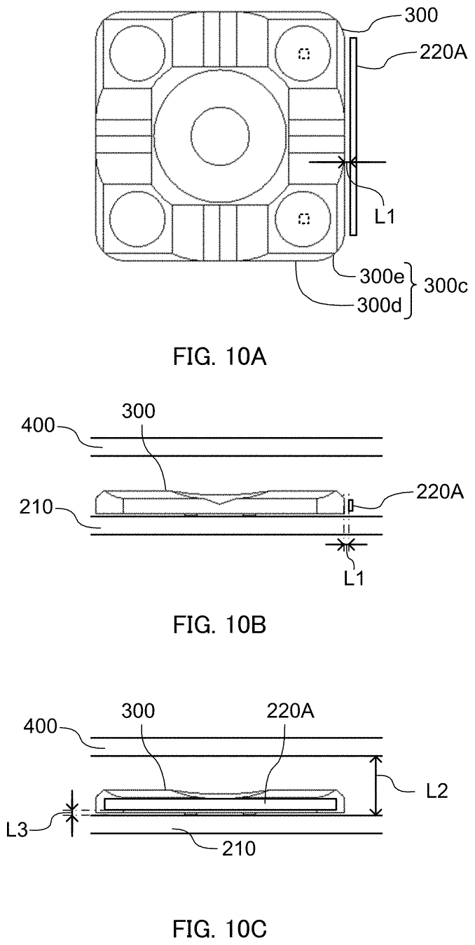

FIG. 10A is a plan view of an apparatus for measuring the illuminance distribution. FIG. 10B is a front view of an apparatus for measuring the illuminance distribution. FIG. 10C is a side view of an apparatus for measuring the illuminance distribution.

As illustrated in FIGS. 10A to 10C, this experiment used the light emitting element (light source 220A) of Lambertian light distribution that has a light emitting surface with a vertical length of 0.6 mm, a lateral length of 14 mm, and provides an emission light wavelength of 550 nm. The light source 220A is not a light source provided in surface light source device 100, but is a light source used only for this experiment. Light flux controlling member 300 with a vertical length of 18 mm and a lateral length 18 mm in plan view was used. Distance L1 between light source 220A and light flux controlling member 300 was set to 0.05 mm. Distance L2 between substrate 210 and light diffusion plate 400 was set to 3 mm. That is, in this experiment, by comparison with surface light source device 100, an excessive quantity of light was entered from first side surface 300d of light flux controlling member 300. The above-described virtual plane corresponds to the surface on light emitting device 200 side of light diffusion plate 400.

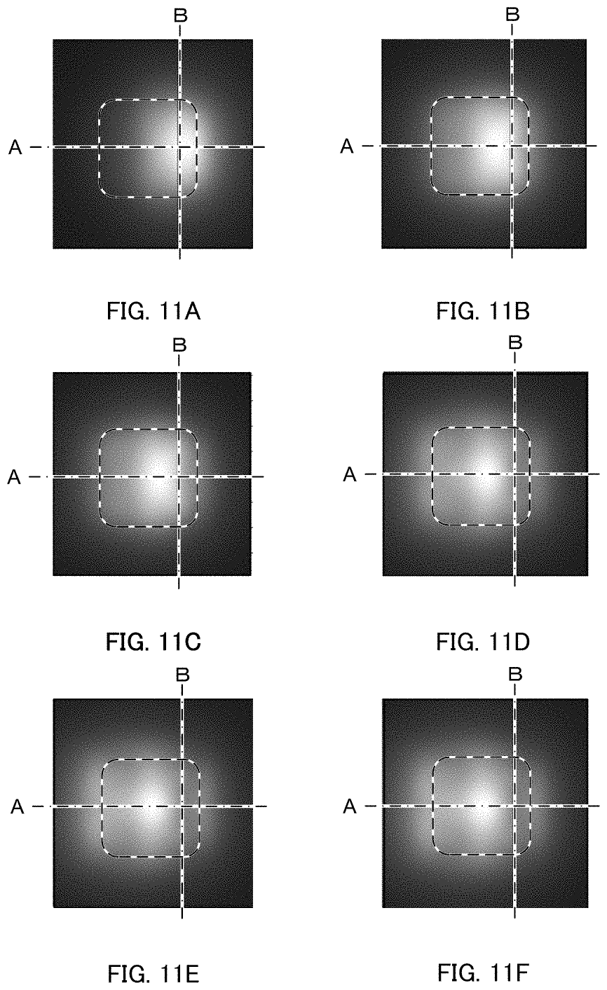

FIG. 11A illustrates a result of a case obtained with a light flux controlling member including an emission promotion part that exhibits Lambertian scattering. FIG. 11B illustrates a result of a case obtained with a light flux controlling member including an emission promotion part that exhibits Cos5 power scattering. FIG. 11C illustrates a result of a case obtained with a light flux controlling member including an emission promotion part that exhibits Cos10 power scattering. FIG. 11D illustrates a result of a case obtained with a light flux controlling member including an emission promotion part that exhibits Cos50 power scattering. FIG. 11E illustrates a result of a case obtained with a light flux controlling member including an emission promotion part that exhibits Cos100 power scattering. FIG. 11F illustrates a result of a case obtained with a light flux controlling member including an emission promotion part that exhibits Cos500 power scattering. The dotted line in FIGS. 11A to 11F indicates the external shape of light flux controlling member 300. Line A illustrated in FIGS. 11A to 11F is a straight line passing through first point P1 located immediately above the center of gravity of light flux controlling member 300 and second point P2 located immediately above the center of first side surface 300d. Line B illustrated in FIGS. 11A to 11F indicates a straight line passing through central axis CA of incidence units 310 disposed adjacent to each other along first side surface 300d where light emitted from light source 220A enters.

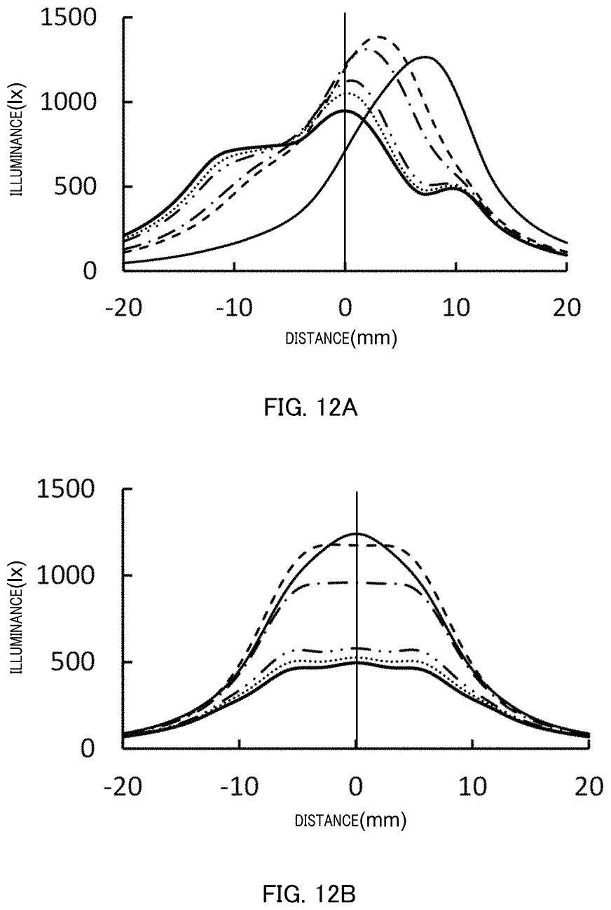

FIG. 12A is a graph illustrating an illuminance distribution on line A illustrated in FIGS. 11A to 11F. FIG. 12B is a graph illustrating an illuminance distribution on line B illustrated in FIGS. 11A to 11F. In FIGS. 12A and 12B, the thin solid line corresponds to FIG. 11A, the broken line corresponds to FIG. 11B, the dashed line corresponds to FIG. 11C, the chain double-dashed line corresponds to FIG. 11D, the dotted line corresponds to FIG. 11E, and the thick solid line corresponds to FIG. 11F. The abscissa in FIGS. 12A and 12B indicates the distance from first point P1 located immediately above the center of gravity of light flux controlling member 300. The ordinate in FIGS. 12A and 12B indicates the illuminance.

Table 1 shows the ratio of the light distribution characteristics of the light reflected by each emission promotion part 323 determined based on the above-described method, the integrated value of the illuminance of the first region, and the integrated value of the illuminance of the second region. More specifically, this is the ratio of the integrated value of the illuminance of the second region and the integrated value of the illuminance of the first region in the range of −9 to +9 mm in FIGS. 12A and 12B.

TABLE 1

| | First Region(%) | Second Region(%) |
|---|---|---|
| Lambertian scattering | 74 | 26 |
| Cos5 power scattering | 59 | 41 |
| Cos10 power scattering | 56 | 44 |
| Cos50 power scattering | 48 | 52 |
| Cos100 power scattering | 46 | 54 |
| Cos500 power scattering | 45 | 55 |

Table 2 shows the ratio of the light distribution characteristics of the light reflected by each emission promotion part 323 determined based on the above-described method, the integrated value of the illuminance of the first region, and the integrated value of the illuminance of the second region. More specifically, this is the ratio of the integrated value of the illuminance of the second region and the integrated value of the illuminance of the first region in the range of −18 to +9 mm in FIGS. 12A and 12B.

TABLE 2

| | First Region(%) | Second Region(%) |
|---|---|---|
| Lambertian scattering | 69 | 31 |
| Cos5 power scattering | 53 | 47 |
| Cos10 power scattering | 48 | 52 |
| Cos50 power scattering | 39 | 61 |
| Cos100 power scattering | 37 | 63 |
| Cos500 power scattering | 35 | 65 |

FIGS. 11A to 12B and Tables 1 and 2 show that regarding the distribution of the light reflected by emission promotion part 323, the integrated value of the illuminance of the first region is higher than the integrated value of the illuminance of the second region with Lambertian scattering to Cos10 power scattering. In addition, FIG. 12A shows that by comparison between the illuminance distribution of the light of Lambertian scattering to Cos10 power scattering and the illuminance distribution of the light of Cos50 power scattering to Cos5000 power scattering, the illuminance around −12 cm from light flux controlling member 300 is low in the illuminance distribution of the light of Lambertian scattering to Cos10 power scattering. This result matches the result of the integrated value of the illuminance of −18 to 0 mm (second region R2) and 0 to +9 mm (first region R1) from light flux controlling member 300 in Table 2.

### Effect of Emission Promotion Part

Here, the effect of emission promotion part 323 was confirmed using light flux controlling member 300 provided with emission promotion part 323 and a light flux controlling member provided with no emission promotion part 323. The measurement condition was the same as the case of determining the integrated value of the illuminance, and therefore the description thereof will be omitted.

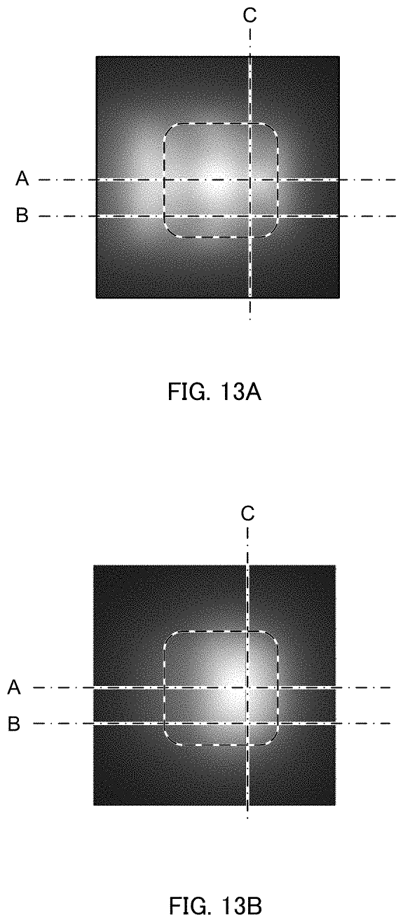

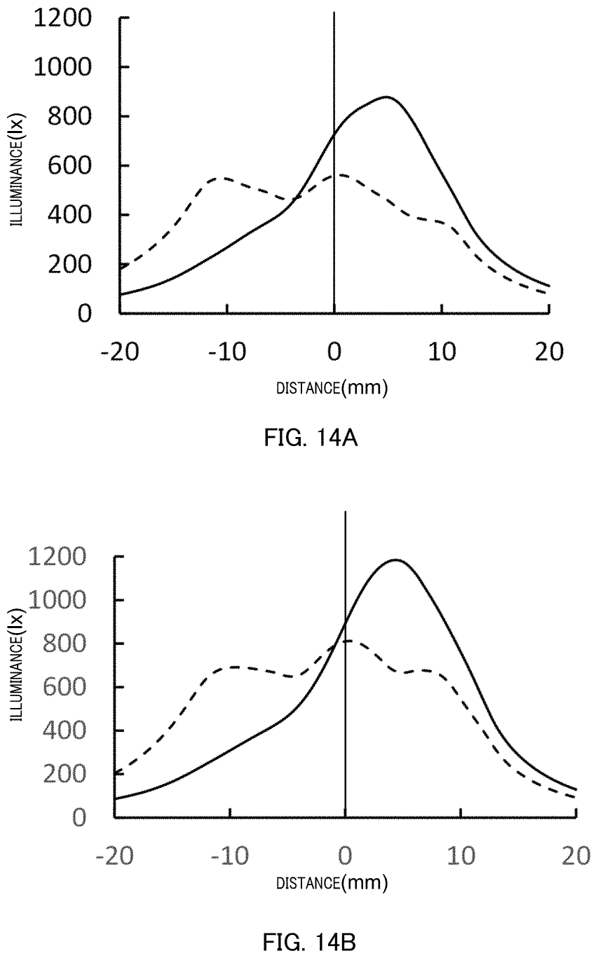

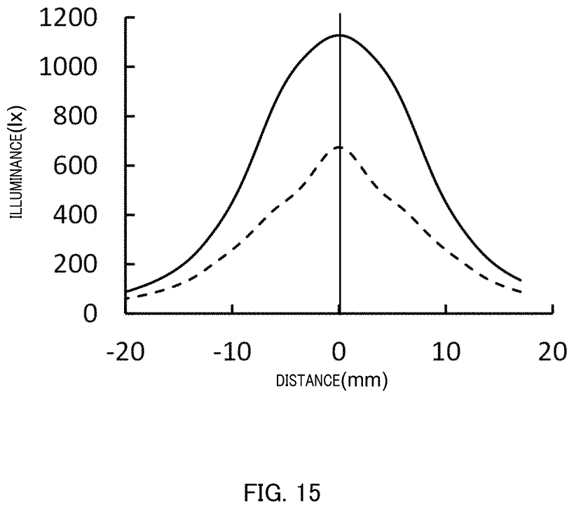

FIG. 13A is the illuminance distribution of the case where the light flux controlling member provided with no emission promotion part 323 was used. FIG. 13B is the illuminance distribution of the case where light flux controlling member 300 of the embodiment of the present invention provided with emission promotion part 323 was used. The dotted line in FIGS. 13A and 13B indicates the external shape of light flux controlling member 300. Line A illustrated in FIGS. 13A and 13B is a straight line passing through first point P1 located immediately above the center of gravity of light flux controlling member 300 and second point P2 located immediately above the center of first side surface 300d. Line B illustrated in FIGS. 13A and 13B is a straight line passing through central axis CA of incidence units 310 adjacent to each other in the direction orthogonal to first side surface 300d where the light emitted from light source 220A enters. Line C illustrated in FIGS. 13A and 13B is a straight line passing through central axis CA of incidence units 310 disposed adjacent to each other along first side surface 300d where the light emitted from light source 220A enters. FIG. 14A is the illuminance distribution on line A of FIGS. 13A and 13B. FIG. 14B is the illuminance distribution on line B of FIGS. 13A and 13B. FIG. 15 is the illuminance distribution on line C of FIGS. 13A and 13B. In FIGS. 14A to 15, the abscissa indicates the distance from first point P1 located immediately above the center of gravity of light flux controlling member 300. In FIGS. 14A to 15, the ordinate indicates the illuminance. In FIGS. 14A to 15, the solid line indicates a result obtained by using light flux controlling member 300 of the embodiment of the present invention provided with emission promotion part 323. In FIGS. 14A to 15, the broken line indicates a result obtained by using the light flux controlling member provided with no emission promotion part 323.

FIGS. 13A to 15 show that in the case where the light flux controlling member provided with no emission promotion part 323 was used, the light is emitted from light emitting device 200 in the first region and second region. A possible reason for this is that the light emitted from light source 220A was emitted while being guided inside the light flux controlling member.

On the other hand, it is shown that in the case where light flux controlling member 300 provided with emission promotion part 323 was used, a larger quantity of light is emitted from first region by comparison between the first region and the second region. A possible reason for this is that emission promotion part 323 disposed at rear surface 300b of light flux controlling member 300 scattered and reflected the light emitted from light source 220A, and as a result the light was emitted while being less guided in comparison with the light flux controlling member provided with no emission promotion part 323.

Next, the illuminance distribution was examined with only one light emitting device 200 turned on, by using surface light source device 100 according to the embodiment of the present invention, and a surface light source device according to a comparative example including the light flux controlling member provided with no emission promotion part 323. Here, nine light emitting devices 200 are disposed in a matrix on grid points of square lattice. Then, only four light emitting elements 220 of the center light emitting device 200 were turned on.

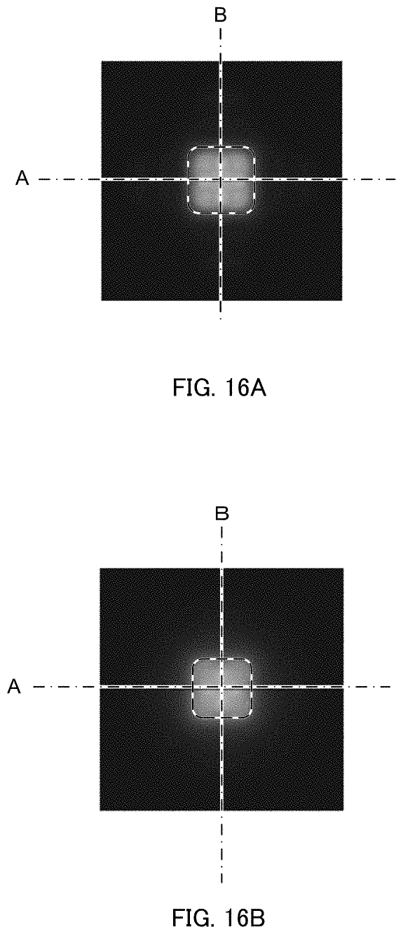

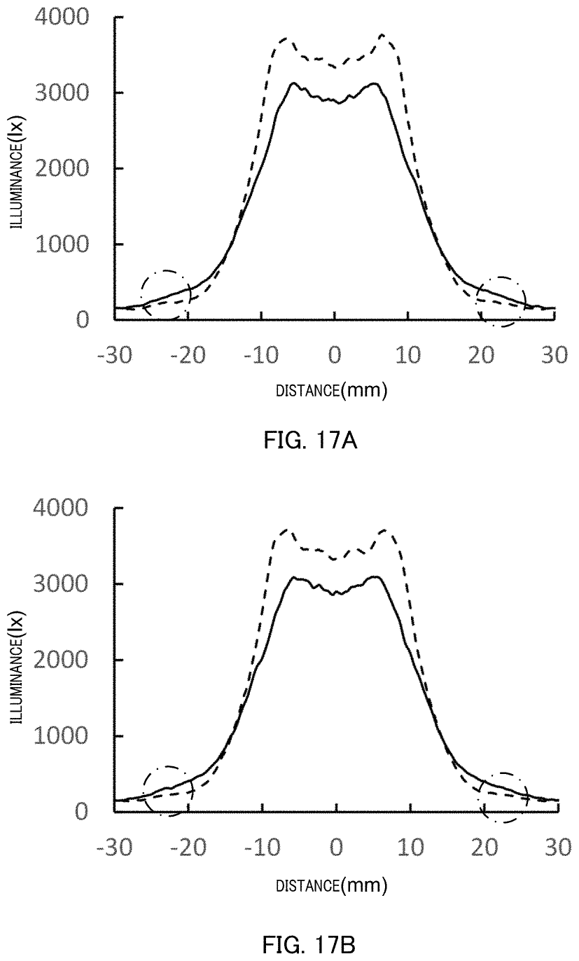

FIG. 16A is an illuminance distribution in the surface light source device according to the comparative example. FIG. 16B is the illuminance distribution in surface light source device 100 according to the embodiment of the present invention. In FIGS. 16A and 16B, the dotted line indicates the external shape of light flux controlling member 300. In FIGS. 14A and 14B, the line A indicates a straight line passing through the center of gravity of light flux controlling member 300 (virtual plane) and the center of the side of light flux controlling member 300. In FIGS. 16A and 16B, line B is a straight line that passes through the center of gravity of light flux controlling member 300 (virtual plane) and is orthogonal to the above-described straight line. FIG. 17A is the illuminance distribution on line A illustrated in FIGS. 16A and 16B. FIG. 17B is the illuminance distribution on line B illustrated in FIGS. 16A and 16B. In FIGS. 17A and 17B, the abscissa indicates the distance from first point P1 located immediately above the center of gravity of light flux controlling member 300. In FIGS. 17A and 17B, the ordinate indicates the illuminance. In FIGS. 17A and 17B, the solid line indicates a result of surface light source device 100 according to the embodiment of the present invention. FIGS. 17A and 17B, the broken line indicates a result of the surface light source device according to the comparative example.

FIGS. 16A to 17B show that in surface light source device 100 according to the embodiment of the present invention, the irregularity in the region surrounded by the dashed line of FIGS. 17A and 17B was reduced in comparison with the surface light source device according to the comparative example. This means that in surface light source device 100 according to the embodiment of the present invention, the light is emitted to the outside of light flux controlling member 300 at emission promotion part 323 of light emitting device 200 (second light emitting device 200) adjacent to light emitting device 200 (first light emitting device 200) including the turned-on light emitting element 220, and thus light propagation to the further light emitting device 200 (third light emitting device 200) adjacent thereto can be suppressed. Thus, it is possible to appropriately illuminate only the vicinity of the region immediately above light emitting device 200 including the turned-on light emitting element 220.

### Effect

As described above, surface light source device 100 according to the present embodiment emits the light entered from first side surface 300d of light flux controlling member 300, from the first region, and thus can suppress the light propagation between light emitting devices 200. In addition, it is possible to illuminate only the vicinity of the region to be illuminated in light diffusion plate 400.

### Industrial Applicability

The surface light source device according to the embodiment of the present invention is applicable to a backlight of a liquid crystal display apparatus, a generally-used illumination apparatus, and the like, for example.

### REFERENCE SIGNS LIST

100 Surface light source device

100′ Display device

102 Display member

110 Housing

112 Bottom plate

114 Top plate

200 Light emitting device

210 Substrate

220 Light emitting element

220A Light source

300 Light flux controlling member

300a Front side surface

300b Rear side surface

300c Side surface

300d First side surface

300e Second side surface

310 Incidence unit

311 Incidence surface

311a First incidence surface

311b Second incidence surface

312 First reflection surface

320 Emission unit

321 First emission unit

322 Second emission unit

323 Emission promotion part

324 First emission part

324a Second reflection surface

324b Emission surface

325 Second emission part

330 Leg part

400 Light diffusion plate

CA Central axis

LA Optical axis

R1 First region

R2 Second region

P1 First point

P2 Second point

P3 Third point

P4 Fourth point

P5 Fifth point

1. A light flux controlling member configured to control a distribution of light emitted from a plurality of light emitting elements disposed on a substrate, the light flux controlling member comprising:
a plurality of incidence units configured to allow incidence of the light emitted from the plurality of light emitting elements; and
a plurality of emission units disposed between the plurality of incidence units in a direction along the substrate, and configured to emit light entered from the plurality of incidence units while guiding the light entered from the plurality of incidence units,
wherein each of the plurality of incidence units includes:
an incidence surface disposed on a rear side of the light flux controlling member, and configured to allow incidence of light emitted from each of the plurality of light emitting elements, and
a first reflection surface disposed on a front side of the light flux controlling member, and configured to laterally reflect light entered from the incidence surface, in a direction away from an optical axis of each of the plurality of light emitting elements;
wherein each of the plurality of emission units includes:
an emission promotion part disposed on the rear side of the light flux controlling member, and configured to promote emission of light being guided inside each of the plurality of emission units, and
an emission part disposed on a front side of the light flux controlling member, and configured to emit light that has been guided inside each of the plurality of emission units; and
wherein when light is entered into the light flux controlling member from a side surface of one emission unit of the plurality of emission units, an integrated value of an illuminance on a virtual line in a first region is greater than an integrated value of an illuminance on the virtual line in a second region on a virtual plane disposed immediately above the light flux controlling member and having a plan shape identical to that of the light flux controlling member, the virtual line passing through a first point located immediately above a center of gravity of the light flux controlling member and a second point located immediately above a center of the side surface on the virtual plane, the first region being located on a second point side with respect to the first point, the second region being located on a side opposite to the second point with respect to the first point.

2. The light flux controlling member according to claim 1, wherein the emission promotion part is disposed in a substantially entire surface except for the incidence surface on the rear side of the light flux controlling member.

3. The light flux controlling member according to claim 1, wherein the emission promotion part is a plurality of recesses or a plurality of protrusions.

4. The light flux controlling member according to claim 1, wherein the emission part includes a second reflection surface configured to reflect, toward the rear side of the light flux controlling member, light reflected by the first reflection surface.

5. The light flux controlling member according to claim 1, wherein a light source that enters light into the light flux controlling member from the side surface of the one emission unit of the plurality of emission units is a planar light source configured to enter the light from at least the side surface between a third point and a fourth point, the third point and the fourth point being points closest to the side surface, from centers of the first reflection surfaces of two incidence units most distant from each other among the plurality of the incidence units disposed along the side surface.

6. The light flux controlling member according to claim 5, wherein a light emitting surface of the planar light source has a shape identical to a shape of the side surface between the third point and the fourth point where the light enters.

7. A light emitting device comprising:
a plurality of light emitting elements; and
the light flux controlling member according to claim 1.

8. A surface light source device comprising:
a substrate;
a plurality of the light emitting devices according to claim 7 disposed on the substrate and separated from each other; and
a light diffusion plate disposed over the plurality of light emitting devices.

9. A display device comprising:
the surface light source device according to claim 8; and
a display member configured to be irradiated with light emitted from the surface light source device.
